(19) United States
(12) Patent Application Publication
(10) Pub. No.: US 2026/0160790 A1
(43) Pub. Date: Jun. 11, 2026

(54) ELECTRICAL DEVICE AND METHOD FOR DETECTING BYPASS FRAUD

(71) Applicant: SAGEMCOM ENERGY & TELECOM SAS, BOIS-COLOMBES (FR)

(72) Inventors: Henri TEBOULLE, BOIS-COLOMBES (FR); Christophe GRINCOURT, BOIS-COLOMBES (FR)

(21) Appl. No.: 19/414,115

(22) Filed: Dec. 9, 2025

(30) Foreign Application Priority Data
Dec. 10, 2024 (FR) 2413803

(51) Int. Cl. G01R 22/06; G01R 11/24

(52) U.S. Cl. CPC G01R 22/066; G01R 11/24

(57) ABSTRACT

A meter intended to be connected between an electrical network and an electrical installation, the electrical network including one or more phase conductors and a neutral conductor, and the electrical installation being configured to operate in power consumption mode or in power production mode. The device includes a power relay on each phase conductor, and at least one microprocessor assembly configured to determine that the electrical installation is operating in energy production mode, open the power relay(s), obtain a measurement of the current flowing in the neutral conductor, and generate an alert based on said measurement when the current flowing in the neutral conductor exceeds a second threshold.

### CROSS-REFERENCE TO RELATED APPLICATIONS

The present application claims priority to French Application No. 2413803 filed with the Intellectual Property Office of France on Dec. 10, 2024, which is incorporated herein by reference in its entirety for all purposes.

### Technical Field

The various exemplary embodiments described in the present disclosure relate to an electrical device, particularly an electrical meter for an electrical installation that can operate in energy consumption mode or in energy production mode (for example, installation fitted with solar panels or wind turbines). They also relate to a method for detecting bypass fraud in such an installation.

### BACKGROUND

The electrical installation is connected via the electrical meter to an electrical network comprising one or more phase conductors and a neutral conductor. The meter typically includes, for each phase conductor, a power relay that can be closed or opened to manage the connection between the electrical network and the electrical installation.

Bypass fraud consists of short-circuiting the meter for one or more phase connectors and optionally for the neutral conductor. It is possible to detect fraud by monitoring the current flowing in the neutral conductor. The fact that the sum of the currents flowing in the phase conductor(s) and in the neutral conductor is non-zero is indicative of fraud.

The detection of fraud is more complex when it involves all the conductors, phase and neutral. In this case, opening the power relay(s) and measuring the voltage across the relay(s) is known. The downstream voltage (electrical installation side) should be very low with respect to the upstream voltage (network side). A low potential difference between the upstream and downstream points indicates a bypass on the phase connector concerned.

However, this method is not applicable to modern installations capable of operating in energy generation mode. In this case, the presence of a high voltage on the installation side, when the power relay is open, is not necessarily an anomaly.

The present disclosure provides a solution for installations that can operate in energy generation mode.

### SUMMARY

The independent claims define several aspects of the present disclosure. Additionally, further aspects or embodiments are defined in the dependent claims.

A first aspect of the present disclosure relates to a method for detecting bypass fraud in an electrical installation connected to an electrical network via an electrical meter, the electrical network comprising one or more phase conductors and a neutral conductor, the electrical installation being configured to operate in energy consumption mode or energy production mode, and the meter comprising a power relay on each phase conductor. The method described herein comprises the following operations: a determination that the installation is operating in energy production mode; an opening of the power relay(s); a measurement of the current flowing in the neutral conductor, and a generation of an alert as a function of said measurement when the current flowing in the neutral conductor exceeds a second threshold.

When the relay(s) are open, the current flowing in the neutral conductor is normally very low. A non-zero current in the neutral conductor indicates bypassing of at least one phase conductor and optionally bypassing of the neutral conductor (the current is then divided between the bypass and the neutral conductor).

This method for detecting fraud is suitable for installations that can operate in energy consumption mode (in which energy is imported from the network into the installation) or in energy production mode (in which energy is exported from the installation to the network). It detects fraud when at least one phase conductor is bypassed. The detection of fraud takes place in energy production mode. This solution is advantageous because it avoids having to open the power relay(s) when the installation is in energy consumption mode. The user is therefore not disturbed by the opening of the relay(s): there is no interruption. When the installation is in energy production mode and the relay(s) are open, the energy produced is reused in the installation. This means that the opening of the relay(s) does not result in any energy loss.

This method also has the advantage of being simple, requiring no additional components compared with existing meters, and therefore not involving any additional costs.

In one embodiment, these operations are repeated periodically as long as no alert has been generated. For example, they can be repeated every hour. The aim herein is to avoid opening the power relays too frequently.

In one embodiment, the method involves calculating a global active power associated with the phase conductor(s), and the determination of operation in production mode when the global active power is negative for a predefined period of time.

In one embodiment, the opening of the power relay(s) occurs after checking that the current flowing in the neutral conductor is greater than a first threshold. This is advantageous in the case of a polyphase network, to avoid any false alarm due to a normal imbalance between the network phases resulting in a non-zero, but normal, current in the neutral conductor.

Another aspect of the present disclosure relates to an electrical device configured to be connected between an electrical network and an electrical installation, the electrical network comprising one or more phase conductors and a neutral conductor, and the electrical installation being configured to operate in an energy consumption mode or an energy production mode. The device comprises a power relay on each phase conductor, connected between the electrical network and the electrical installation, and at least one microprocessor assembly configured to perform the operations disclosed hereinbefore.

Another aspect relates to a computer program product comprising instructions which when executed by at least one processor cause the fraud detection method disclosed hereinbefore to be implemented.

Another aspect relates to a non-transitory computer-readable storage medium comprising instructions which when executed by a processor cause the fraud detection method described hereinbefore to be implemented.

### BRIEF DESCRIPTION OF THE FIGURES

The embodiments will be better understood in light of the following detailed description and the accompanying drawings, which are given by way of illustration only and therefore do not limit the present disclosure.

FIG. 1 is a block diagram of a first example of an electrical device according to the present disclosure, in the case of a single-phase network, in the absence of fraud.

FIG. 2 is a block diagram of the same example of an electrical device as shown in FIG. 1, in the case of fraud by bypassing the phase conductor and the neutral conductor.

FIG. 3 is a block diagram of a second example of an electrical device according to the present disclosure, in the case of a three-phase network, with fraud by bypassing the phase conductors and the neutral conductor.

FIG. 4 is a flowchart of a fraud detection method intended to be implemented in a device of the type described in FIG. 1 to FIG. 3.

### DETAILED DESCRIPTION

Various embodiments will now be described in more detail, non-limitingly, with reference to the drawings accompanying the present disclosure and showing certain exemplary embodiments.

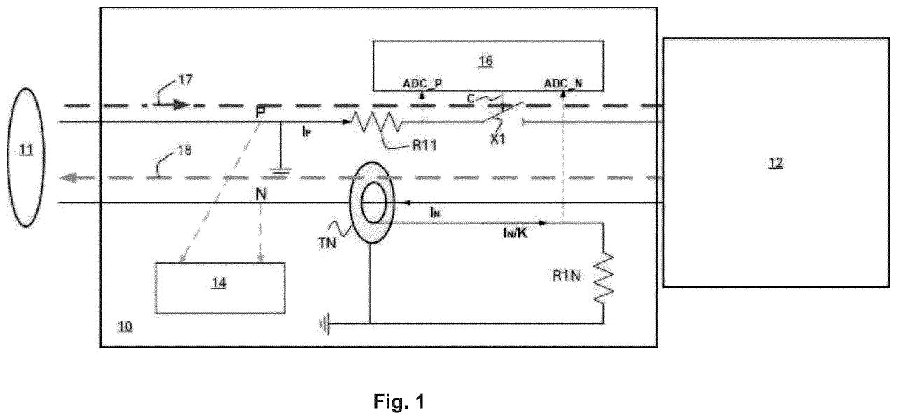

FIG. 1 discloses an electrical device 10 connected between a single-phase electrical network 11 and an electrical installation 12. The network 11 comprises a phase conductor P, which in this embodiment is connected to earth, and a neutral conductor N, which in this example is connected to the high voltage point (typically 230V). The device 10 also comprises a power supply 14 connected to the two connectors P and N, and a microprocessor 16. The microprocessor 16 has at least one metrology function, that is, measurement of currents and voltages at various points and calculation of the energy imported and exported by the installation 12 (typically the microprocessor 16 includes sensors and an analog-to-digital converter to obtain samples at a sampling frequency from which it performs the calculations). A measuring resistor R11 (shunt) is connected to the phase connector P upstream of a power relay X1 connected to the installation 12. The measuring resistor R11 is used to measure a current I_{P} flowing through the phase conductor P. The power relay X1 is used to disconnect the installation 12 from the network 11. A transformer TN, with a ratio K (typically 2000), is connected to the neutral conductor N. A resistor R1N (typically 10 Ohms) connects the secondary of the transformer TN to earth. By measuring the voltage across the resistor R1N, it is possible to determine the current I_{N}/K, and thus deduce the current I_{N} flowing in the conductor N. The use of a transformer on the neutral conductor is necessary to ensure insulation between the phase conductor and the neutral conductor. The microprocessor 16 controls the power relay X1 as indicated by arrow C. In the figure FIG. 1, the installation 12 is operating in consumption mode: the current in the phase conductor flows from the network 11 to the installation 12 (arrow 17). The current in the neutral connector flows from the installation 12 to the network 11 (arrow 18).

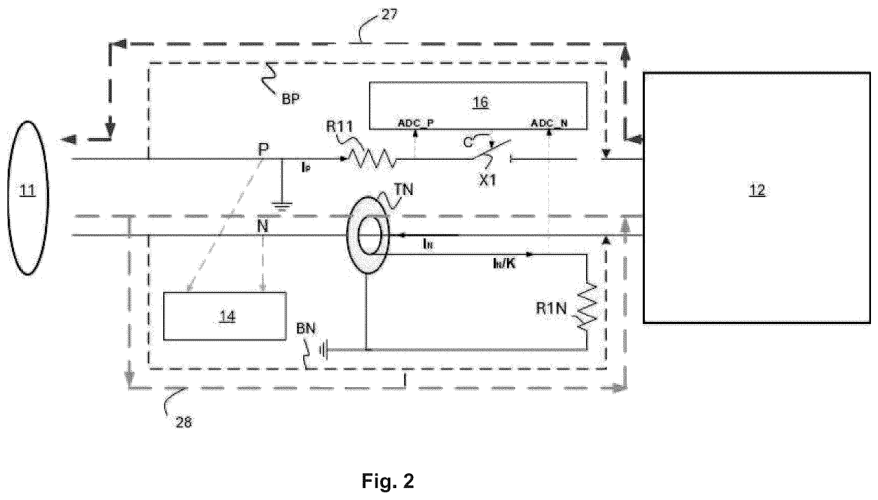

FIG. 2 shows the same example of an electrical device as FIG. 1, in the case of bypass fraud of the phase conductor P and the neutral conductor N. The bypasses of the phase conductor P and the neutral conductor N are referenced BP and BN respectively. In FIG. 2, we consider the case where the installation is operating in energy production mode and the power relay X1 is open: the current flows via bypass BP from the installation 12 to network 11 (arrow 27), and via the bypass BN from the network 11 to the installation 12 (arrow 28). A part of the current also flows in the neutral conductor N of the network 11 to the installation 12.

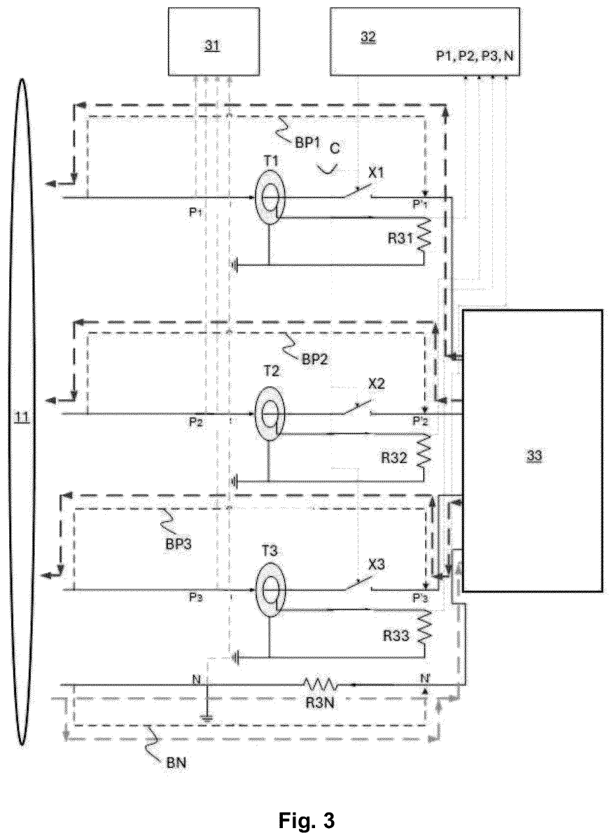

FIG. 3 depicts a second example of an electrical device according to the present disclosure, in the case of a three-phase network, with bypass fraud of the phase conductors and the neutral conductor. In this example, the network has three phase conductors P1, P2 and P3 and a neutral conductor N. The phase conductors P1, P2 and P3 are connected to the high voltage point. The neutral conductor N is connected to earth. The device also includes a power supply 31 connected to the four conductors and a microprocessor 32 which, like the microprocessor 16, has at least one metrology function, that is, measurement of currents and voltages at various points and calculation from these measurements. In this embodiment, a measuring resistor R3N (shunt) is connected to the neutral connector N between the network 11 and the installation 33. The measuring resistor R3N measures a current I_{N} flowing through the neutral conductor N. On each phase connector P1, P2 and P3, a measuring transformer T1, T2 and T3 respectively, are connected in series with a power relay X1, X2 and X3 respectively. The three power relays X1, X2 and X3 are used to disconnect the installation 33 from the network 11. They are controlled by the same C command supplied by microcontroller 32. As disclosed previously for the single-phase network, the resistors R31, R32 and R33 connected to the secondaries of the transformers T1, T2 and T3 make it possible to obtain the current flowing through each of the phase connectors P1, P2 and P3. FIG. 3 also depicts the bypasses BP1, BP2, BP3 and BN for the four conductors.

In addition to the metrological functions mentioned above, the microprocessor shown in FIG. 1 to FIG. 3 can be configured to implement the method for detecting bypass fraud disclosed hereafter. It is also possible to use a separate application microprocessor to implement the fraud detection functions from data communicated by the metrological microprocessor.

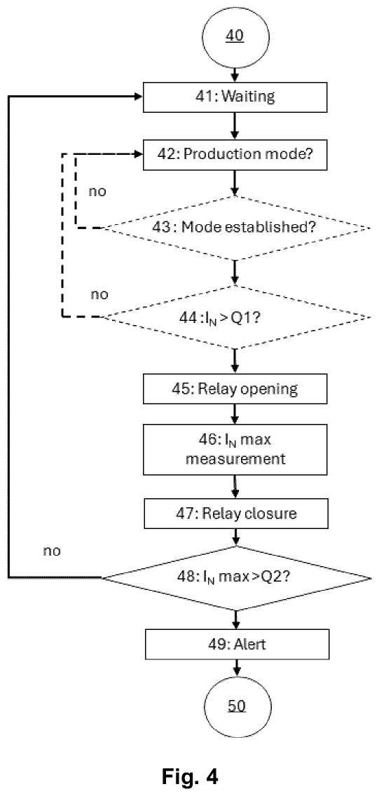

An exemplary embodiment of an algorithm for implementing a method for detecting bypass fraud according to the present disclosure is depicted in FIG. 4. This algorithm uses a first current threshold Q1, equal to 500 mA for example, and a second current threshold Q2, equal to 250 mA for example. In one embodiment, the value of current thresholds Q1 and Q2 is programmable. The algorithm starts in 40, with the power relay(s) X1 to X3 being closed. In 41, waiting for a pre-determined duration, for example 1h. This waiting phase is intended to prevent the power relay(s) from being opened too often in production mode. In 42, determining whether the installation is operating in production mode. The production operating mode is detected when the overall active power associated with the phase conductor(s) is negative (that is, the sum of the active powers for each phase). Advantageously, in 43, it is checked that the production operating mode has been established, for example that the installation has been operating in production mode for a certain time, for example 60s. If the overall active power is not negative for a sufficiently long time (60s in this example), the algorithm resumes in 42. Otherwise, it continues in 44. Step 44 is optional, particularly advantageous in the case of a multiphase network. In 44, checking whether the current flowing through the neutral conductor I_{N} is greater than the first threshold Q1. For example, this can be done by checking whether the first threshold Q1 is reached at least once over a period of, for example, 10s. If not, the algorithm resumes in 42. Otherwise, it continues in 45. In 45, a command is sent by the microprocessor to open the power relay(s). Then in 46, the maximum neutral current is measured. This can be done, for example, by determining a neutral current value every second and retaining the maximum value from the ten measurements obtained. Then in 47, closing the power relay(s), and in 48, checking whether the retained neutral current value is greater than the second threshold Q2. If not, no fraud is detected, the algorithm resumes in 41. Otherwise, in 49, an alert is generated and transmitted to the electrical network operator via a modem on the electrical device. The algorithm ends in 50.

The specific structural and functional details disclosed herein are non-limiting examples. They may be subject to various modifications, alternative forms, additions or deletions without departing from the scope of the disclosure as determined on the basis of the claims and their equivalents.

Any suitable data-processing system can be used for the implementation. An appropriate data-processing system or device comprises for example a combination of software code and circuits, such as a processor, controller or other circuit suitable for executing the software code. When the software code is executed, the processor or controller prompts the system or device to implement all or part of the functionalities of the blocks and/or phases of the methods according to the exemplary embodiments. The software code can be stored in non-volatile memory or on a non-volatile storage medium (USB key, memory card or other medium) that can be read directly or via a suitable interface by the processor or controller.

For example, it is possible to use one or more microprocessor assemblies, for example, a first microprocessor assembly responsible for the metrological functions of the meter (current and voltage measurement) communicating with a second microprocessor assembly responsible for the application functions of the meter, for example, the implementation using the measurements provided by the first microprocessor of the method for detecting bypass fraud as described herein.

Advantages and solutions to problems have been described above with regard to specific embodiments of the invention. They should not be construed as a critical, required or essential feature or element of any or all of the claims.

1. An electrical device configured to be connected between an electrical network and an electrical installation, the electrical network comprising one or more phase conductors and a neutral conductor, and the electrical installation being configured to operate in energy consumption mode or in energy production mode, the device comprising a power relay on each phase conductor, connected between the electrical network and the electrical installation, and at least one microprocessor assembly configured to perform the following operations:
determine that the electrical installation is operating in energy production mode,
open the power relay or relays,
obtain a measurement of the current flowing in the neutral conductor, and
generate an alert based on said measurement when the current flowing in the neutral conductor exceeds a second threshold.

2. The device according to claim 1, wherein the at least one microprocessor assembly is configured to repeat said operations periodically as long as no alert has been generated.

3. The device according to claim 1, wherein the at least one microprocessor assembly is configured to calculate a global active power associated with the phase conductor or conductors, and to determine that the electrical installation is operating in energy production mode when the global active power is negative for a predefined period of time.

4. The device according to claim 1, wherein the at least one microprocessor assembly is configured so as to, before opening the power relay or relays, check that the current flowing in the neutral conductor is greater than a first threshold.

5. A method for detecting bypass fraud in an electrical installation connected to an electrical network via an electrical meter, the electrical network comprising one or more phase conductors and a neutral conductor, the electrical installation being configured to operate in an energy consumption mode or in an energy production mode, and the meter comprising a power relay on each phase conductor, the method comprising:
a determination of the operation of the installation in energy producer mode,
an opening of the power relay or relays,
a measurement of the current flowing in the neutral conductor, and
a generation of an alert based on said measurement when the current flowing in the neutral conductor exceeds a second threshold.

6. The method according to claim 5, wherein said operations are repeated periodically as long as no alert has been generated.

7. The method according to claim 5, further comprising a calculation of a global active power associated with the phase conductor or conductors, and in that said determination is made when the global active power is negative for a predefined period of time.

8. The method according to claim 5, wherein the opening of the power relay or relays occurs after checking that the current flowing through the neutral conductor is greater than a first threshold.

9. A non-transitory computer-readable storage medium comprising instructions which when executed by a processor cause the implementation of a method according to claim 5.
